(19) United States
(12) Patent Application Publication
(10) Pub. No.: US 2006/0214197 A1
(43) Pub. Date: Sep. 28, 2006

(54) Semiconductor device

(75) Inventors: Kazutoshi Nakamura, Yokohama-shi (JP); Yusuke Kawaguchi, Miura-gun (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/358,225

(22) Filed: Feb. 22, 2006

(30) Foreign Application Priority Data
Feb. 22, 2005 (JP) 2005-045501

(51) Int. Cl. H01L 29/76

(52) U.S. Cl. 257/288

(57) ABSTRACT

A semiconductor device comprises a semiconductor substrate of a first conductivity type; a semiconductor layer of the first type on the semiconductor substrate; a base layer of a second conductivity type on a surface of the semiconductor layer; a gate insulator formed on sidewalls of each of trenches formed through the base layer; a bottom insulator formed at a bottom of each of the trenches and extending through the semiconductor layer and into the semiconductor substrate; a gate electrode provided in each of the trenches and insulated from the semiconductor substrate, semiconductor layer and base layer by the bottom and gate insulators; source regions of the first type on a surface of the base layer; contact regions of the second type on the surface of the base layer; the bottom insulator having a thickness extending between the semiconductor substrate and the gate electrode, the gate insulator having a thickness extending between the base layer and the gate electrode, the thickness of the bottom insulator being greater than the thickness of the gate insulator, the adjacent two of the trenches each having a width greater than a distance between the adjacent two trenches.

### CROSS-REFERENCE TO RELATED APPLICATION

The present application is based upon and claims the benefit of priority from Japanese Patent Application No. 2005-045501, filed on Feb. 22, 2005, the entire contents of which are incorporated herein by reference.

### BACKGROUND

The present application relates to semiconductor devices for high speed switching and/or high power applications and more particularly to vertical field effect transistors.

Synchronous rectifier systems are increasingly being used with a growing demand for lower voltage power supplies for use in CPUs (Central Processing Units). The synchronous rectifier systems have a feature that, over intermediate potential range interconnecting a high side and a low side, a voltage rate dv/dt, with respect to time, grows larger as operating frequency increases. This feature is known to cause occurrence of “self-turn-on phenomenon”, in which a switching element on the low side cannot maintain its off-state when it is set to the state and shifts to its on-state due to the voltage rate dv/dt of drain voltage.

As one of countermeasures considered effective to prevent the occurrence of this phenomenon, in addition to lowering resistance of a gate, it is important to pay attention to a capacity ratio between a gate-drain capacitance Cgd between gate and drain and a gate-source capacitance Cgs between gate and source. Moreover, it is also important to pay attention to the diode reverse recovery current. The dead time is provided to prevent a high side element and a low side element from turning ON simultaneously. However, the provision of dead time cannot prevent switching loss, which may be brought about by passing through the high side element the reverse recovery current upon reverse recovery of a body diode for the low side element because current passes through this body diode. Accordingly, reducing the reverse recovery current is important.

Referring to the accompanying drawings, FIG. 11 illustrates a cross sectional representation of a portion of a conventional MOSFET (Metal Oxide Semiconductor Field Effect Transistor). For simplification of the description, the explanation proceeds on an N-channel MOSFET, but the same explanation is applicable to a P-channel MOSFET if all conductivity types are reversed. In FIG. 11, the MOSFET is generally denoted by the reference numeral 1 and comprises a heavily doped N⁺-type semiconductor substrate 2 and a lightly doped N⁻-type semiconductor layer 3 that is epitaxially formed on the substrate 2. Formed into the layer 3 is a P-type base region 4. Formed into the P-type base region 4 are heavily doped P⁺-type contact regions 9 and heavily doped N⁺-type source regions 8, each interconnecting and overlapping the adjacent two P⁺-type contact regions 9. The P⁺-type contact regions 9 and the N⁺-type source regions 8 extend adjacent an upper surface of the P-type base region 4.

The MOSFET 1 has a plurality of trenches, only one being shown at 5. The trenches may be patterned as stripes extending in a third dimension (not shown). Each trench 5 is etched completely through one of the N⁺-type source regions 8 and the P-type base region 4, and into the underlying layer 3. Each trench 5 includes a thin gate insulator 6 grown on the trench sidewalls and trench bottom. A conductive gate electrode of polycrystalline silicon 7 is provided to fill each trench 5. Top metallization in ohmic contact with the source and contact regions 8 and 9 and bottom metallization on a lower surface of the N⁺-type semiconductor substrate 2 are formed to provide source and drain contacts 10 and 11, respectively.

A reduction in volume of the N⁻-type semiconductor layer 3 is known to be effective to reduce the diode reverse recovery current. In the conventional device, the N⁻-type semiconductor layer 3 extends over the whole device area, providing increased tendency to collect diode accumulating electric charges upon application of a forward bias, causing an increase in reverse recovery current. In the conventional device, the trenches having a narrow trench width are formed to reduce a gate-drain capacitance Cgd between the gate electrode 7 and the drain contact 11. The narrow trench width leads to a narrow cross sectional area of the gate electrode 7 in each trench, posing a problem that the gate resistance increases.

Japanese Patent Application Laid-open No. 5-335582 (1993), Japanese Patent Application Laid-open No. 2001-119023, Japanese Patent Application Laid-open No. 7-326755 (1995), and U.S. Pat. No. 5,915,180 disclose devices similar to the previously discussed device. U.S. Pat. No. 5,915,180 corresponds to Japanese Patent Application Laid-open No. 7-326755 (1995).

### SUMMARY

A semiconductor device according to the present application comprises: a semiconductor substrate of a first conductivity type; a semiconductor layer of the first conductivity type formed on the semiconductor substrate; a base layer of a second conductivity type formed in a surface of the semiconductor layer; a gate insulator formed on sidewalls of each of trenches formed through the base layer; a bottom insulator formed at a bottom of each of the trenches and extending through the semiconductor layer and into the semiconductor substrate; a gate electrode provided in each of the trenches and insulated from the semiconductor substrate, semiconductor layer and base layer by the bottom and gate insulators; source regions of the first conductivity type formed in a surface of the base layer; contact regions of the second conductivity type formed in the surface of said base layer; the bottom insulator having a thickness extending between the semiconductor substrate and the gate electrode, the gate insulator having a thickness extending between the base layer and the gate electrode, the thickness of the bottom insulator being greater than the thickness of the gate insulator, the adjacent two of the trenches each having a width greater than a distance between the adjacent two trenches.

### BRIEF DESCRIPTION OF THE DRAWINGS

FIG. 1 is a cross representation showing a portion of a semiconductor device in the form of a MOSFET according to a third embodiment;

FIG. 2 is a plan representation of a portion of a semiconductor device in the form of a MOSFET according to a second embodiment;

FIG. 3 is a cross sectional representation taken through the line Y-Y′ in FIG. 2;

FIG. 4 is a cross sectional representation taken through the line X-X′ in FIG. 2;

FIG. 5 is a plan representation showing a portion of a semiconductor device in the form of a MOSFET according to a third embodiment;

FIG. 6 is a cross sectional representation showing a portion of a semiconductor device in the form of a MOSFET according to a fourth embodiment;

FIG. 7 is a cross sectional representation showing a portion of a semiconductor device in the form of a MOSFET according to a fifth embodiment;

FIG. 8 is a cross sectional representation showing a portion of a semiconductor device in the form of a MOSFET according to a sixth embodiment;

FIG. 9 is a cross sectional representation showing a portion of a semiconductor device in the form of a MOSFET according to a seventh embodiment;

FIG. 10 is a cross sectional representation showing a portion of a semiconductor device in the form of a MOSFET according to an eighth embodiment; and

FIG. 11 is a cross sectional representation showing a portion of the conventional MOSFET.

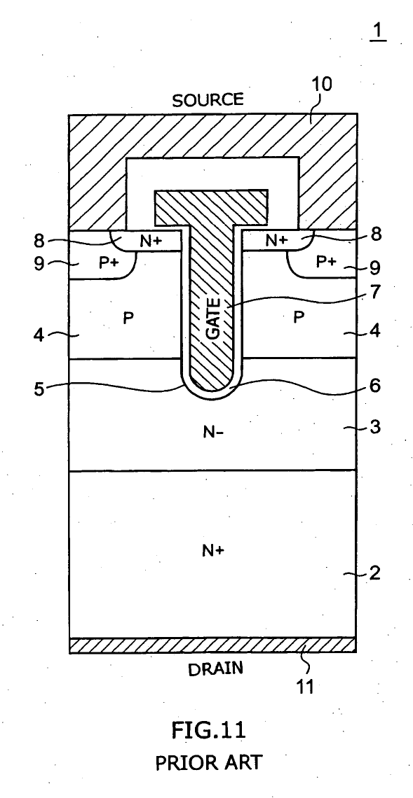

### DESCRIPTION OF THE EMBODIMENTS

### First Embodiment

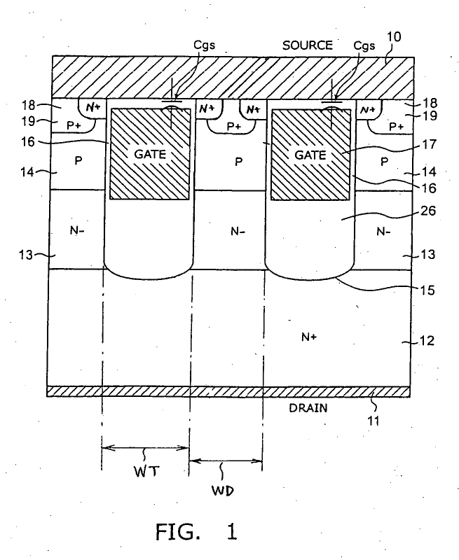

Referring to FIG. 1, a semiconductor device in the form of a MOSFET according to the first embodiment is described. FIG. 1 illustrates a cross sectional representation of a portion of a MOSFET. The MOSFET comprises a heavily doped N⁺-type semiconductor substrate 12 and a lightly doped N⁻-type semiconductor layer 13 that is epitaxially formed on the substrate 12. Formed into the N⁻-type semiconductor layer 13 is a P-type base region 14. Formed into the P-type base region 14 are heavily doped P⁺-type contact regions 19 and heavily doped N⁺-type source regions 18, each interconnecting and overlapping the adjacent two P⁺-type contact regions 19. The P⁺-type contact regions 19 and the N⁺-type source regions 18 extend adjacent an upper surface of the P-type base region 14 over areas where trenches are to be formed or etched. The MOSFET has a plurality of trenches, only one being shown at 15. The trenches may be patterned as stripes extending in a third dimension (not shown). Each trench 15 is formed or etched completely through one of the N⁺-type source regions 18 and P-type base region 14 and into the N⁻-type semiconductor layer 13. At the bottom of each trench 15, a thick insulator 26 is formed. The thick bottom insulator 26 may be formed by ion implantation into the bottom of the trench 15. The thick bottom insulator 26 extends completely through the N⁻-type semiconductor layer 13 and into the N⁺-type semiconductor substrate 12. A thin gate insulator 16 is grown on the trench sidewalls of the trench 15. A conductive gate electrode of polycrystalline silicon 17 is provided to fill the trench 15.

The thick bottom insulator 26 is thicker than the gate insulator 16 and extends between the gate electrode of polycrystalline silicon 17 and the N⁺-type semiconductor substrate 12. Top metallization in ohmic contact with the source and contact regions 18 and 19 and bottom metallization on a lower surface of the N⁺-type semiconductor substrate 12 are formed to provide source and drain contacts 10 and 11, respectively.

While, in the first embodiment, a first conductivity type is N-type and a second conductivity type is P-type, reversal of all conductivity types will result in a complementary device. In this case, the first conductivity type is P-type and the second conductivity type is N-type. Using the first and second conductivity types, it may be described that the semiconductor device according to the first embodiment comprises a semiconductor substrate 12 of a first conductivity type, a first conductivity type semiconductor layer 13 formed on the semiconductor substrate 12, a second conductivity type base layer 14 provided on the first conductivity type semiconductor layer 13, a gate insulator 16 formed on sidewalls of each of a plurality of trenches 15 that are formed completely through the second conductivity type base layer 14, a second insulator 26 formed at the bottom of the trench 15 and extending completely through the first conductivity type semiconductor layer 13 and into the first conductivity type semiconductor substrate 12, a gate electrode 17, within the trench 15, insulated by the gate insulator 16 and the second insulator 26 from the first conductivity type semiconductor substrate 12, the first conductivity type semiconductor layer 13 and the second conductivity type base layer 14, first conductivity type source regions 18 formed into an upper surface of the second conductivity type base layer 14 and adjacent the gate insulator 16, and second conductivity type base contact regions 19 selectively formed into the upper surface of the second conductivity type base layer 14. In this semiconductor device, the second insulator 26 has a thickness that extends between the gate electrode 17 and the semiconductor substrate 12, and this thickness of the second insulator 26 is greater than a thickness of the gate insulator 16. The thickness of the gate insulator 16 extends between the gate electrode 17 and the second conductivity type base layer 14. The trench 15 has a width WT This trench width WT is greater than a distance WD to the adjacent trench 15.

In the first embodiment, the distance WD between the adjacent two trenches 15 is narrower as compared to the width WT of one or each of the trenches 15. Narrowing the distance between the adjacent two trenches 15 has reduced the volume of the N⁻-type semiconductor layer 13, reducing the amount of diode accumulating electric charges collected upon application of a forward bias, thus bringing down the reverse recovery current to a satisfactorily low level. Provision of the thick second or bottom insulator 26 extending between the polycrystalline silicon 17 and the N⁺-type semiconductor substrate 12 has reduced the gate drain capacitance Cgd, allowing the use of trenches 15 wide enough to decrease the gate resistance to a satisfactorily low level.

The thin gate insulator 16 grown on the trench sidewalls is continuous with the thick second or bottom insulator 26. The width of the trench 15 is greater than the distance to the adjacent trench 15 (not illustrated). This distance between the adjacent two trenches 15 is less than or equal to 1 μm. The increased trench width causes an increase in area through which the gate electrode (polycrystalline silicon 17) and the source contact 10 are opposed to each other. This increase in the area causes an increase in the gate source capacitance Cgs. Accordingly, the decreased gate resistance increases the gate source capacitance Cgs, making contribution to a reduction in the capacitance ratio Cgd/Cgs.

### Second Embodiment

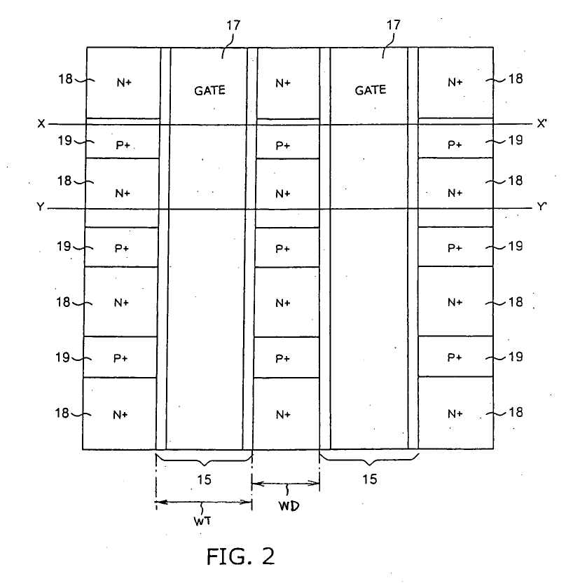

FIGS. 2 to 4 illustrate a semiconductor device in the form of MOSFET according to the second embodiment. In fabrication of the semiconductor device according to the previously described first embodiment, the narrow distance between the adjacent two trenches makes it difficult to form the N⁺-type source regions 18 and P⁺-contact regions 19 in exact parallel relationship with the trenches, respectively. If they were greatly deviated from areas where trenches are to be formed later, the N⁺-type source regions 18 might not remain on the both sides of the top opening of each of the trenches. The second embodiment is addressed to this problem. According to the second embodiment, N⁺-type source regions 18 and P⁺-type contact regions 19 are formed in one plane in juxtaposed relationship without any overlap to provide increased tolerance for deviation from areas where trenches are to be formed. The second conductivity type (the P⁺-type) contact regions 19 and the first conductivity type (the N⁺-type) source regions 18 may be stripes extending across areas where the trenches are to be formed. Viewing in FIG. 2, the second conductivity type contact regions 19 and the first conductivity type source regions 18 extend in a direction orthogonal to a direction along which electric current flows. The trench width WT is greater than a distance WD to the adjacent trench 15.

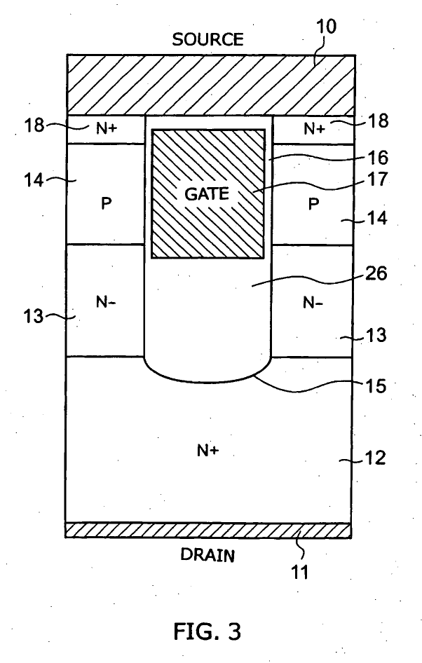

Viewing in FIG. 3 that is the cross sectional representation taken through the line Y-Y′ in FIG. 2, provided between a source contact 10 provided over the illustrated plane in FIG. 2 and a drain contact 11 at the bottom are, similarly to the first embodiment illustrated in FIG. 1, a heavily doped N⁺-type semiconductor substrate 12, a lightly doped N⁻-type semiconductor layer 13, a drift layer, epitaxially formed on the substrate 12, a P-type base region 14 formed into the N⁻type semiconductor layer 13, the heavily doped N⁺-type source region 18 formed into the P-type base region in ohmic contact with the base contact 10, and one of a plurality of trenches shown at 15 formed or etched completely the N⁺-type source region 18 and P-type base region 14 and into the N⁻-type semiconductor layer 13. At the bottom of each trench 15, a thick second insulator 26 is formed. The thick second or bottom insulator 26 may be formed by ion implantation into the bottom of the trench 15. The thick second or bottom insulator 26 extends completely through the N⁻-type semiconductor layer 13 and into the N⁺-type semiconductor substrate 12. A thin gate insulator 16 is grown on the trench sidewalls of the trench 15. A conductive gate electrode of polycrystalline silicon 17 is provided to fill the trench 15.

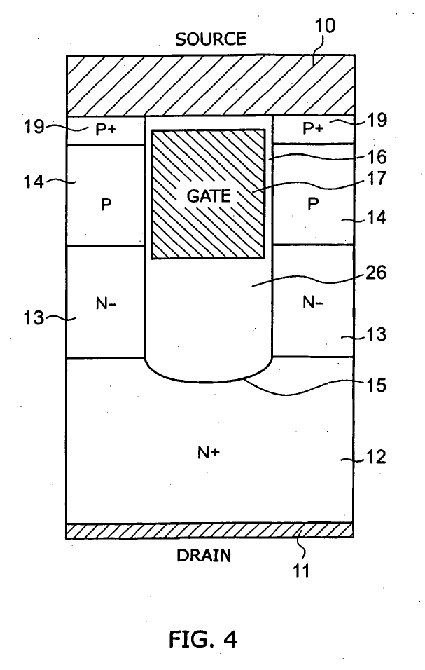

The thick bottom insulator 26 is thicker than the thin gate insulator 16 and extends between the gate electrode of polycrystalline silicon 17 and the N⁺-type semiconductor substrate 12. Viewing in FIG. 3, the thick bottom insulator 26 extends between the N⁺-type semiconductor substrate 12 and a lower end of the gate electrode of polycrystalline silicon 17 to separate them each other. Although not shown in the illustrated cross sectional representation taken through the line Y-Y′, the N⁺-type source region 18 is interposed between the adjacent two P⁺-type contact regions 19 as will be readily seen from the cross sectional representation taken through the line X-X′ in FIG. 4 and the illustrated plan representation in FIG. 2. Top metallization in ohmic contact with the source and contact regions 18 and 19 is formed to provide the source contact 10.

Referring to FIG. 4, the illustrated cross sectional representation taken through the line X-X in FIG. 2 is generally the same as the cross sectional representation illustrated in FIG. 3. As is readily seen from FIG. 4, the P⁺-type contact region 19 is formed into the P-type base region 14 on the opposite sides of and adjacent the trench 15. According to the second embodiment, N⁺-type source regions 18 and P⁺-type contact regions 19 are formed in one plane in juxtaposed relationship without any overlap to provide increased tolerance for deviation from areas where trenches are to be formed.

### Third Embodiment

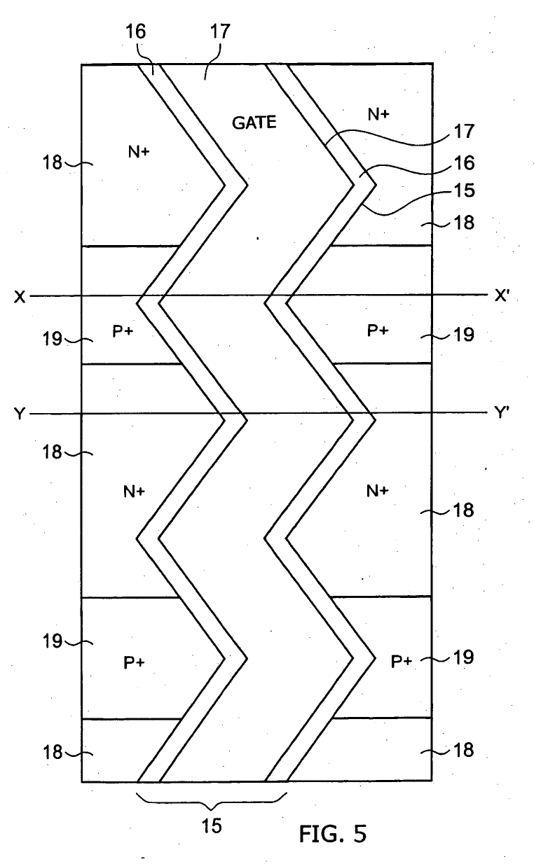

Referring to FIG. 5, a MOSFET according to the third embodiment has a higher cell density as compared to the first and second embodiments by employing, viewing in the plan, a zigzag gate electrode of polycrystalline silicon 17. As is seen from the plan view of the second embodiment illustrated in FIG. 2, the first and second embodiments employ a gate electrode of polycrystalline silicon 17 lying in a straight course below the source contact 10. In the MOSFET according to the third embodiment, as shown in FIG. 5, the zigzag gate electrode of polycrystalline silicon 17 is undulating across a direction in which electric current flows in generally orthogonal manner.

Cross sectional representations taken through the line Y-Y′ and X-X′ in FIG. 5 have the same cross sectional views illustrated in FIGS. 3 and 4, respectively. Accordingly, with reference also to FIGS. 3 and 4, the MOSFET according to the third embodiment illustrated in FIG. 5 is described. As shown in FIG. 5, each of a plurality of trenches 15 is a zigzag trench having a predetermined width. Each zigzag trench 15 includes a gate insulator formed on the undulating trench sidewalls. Referring also to FIGS. 3 and 4, the zigzag trench 15 is formed or etched completely through the N⁺-type source regions 18 and P-type base regions 14 and into the N⁻-type semiconductor layer 13. At the bottom of the zigzag trench 15, a thick insulator 26 is formed. The thick bottom insulator 26 may be formed by ion implantation into the bottom of the trench 15. The thick bottom insulator 26 extends completely through the N⁻-type semiconductor layer 13 and into the N⁺-type semiconductor substrate 12. A thin gate insulator 16 is grown on the undulating trench sidewalls of the trench 15. A conductive gate electrode of polycrystalline silicon 17 is provided to fill the zigzag trench 15 to make a zigzag gate electrode undulating as illustrated in FIG. 5. The use of the zigzag gate electrode provides a high cell density, making it possible to reduce ON resistance of the MOSFET.

### Fourth Embodiment

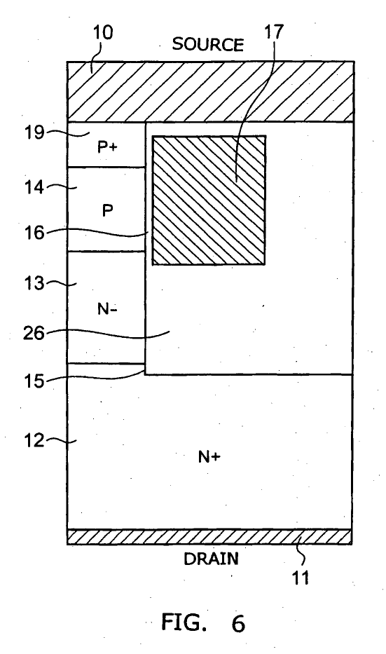

Referring to FIG. 6, a MOSFET according to the fourth embodiment is described. Turning back to FIG. 2, a gate electrode of polycrystalline silicon 17 extends to form a column. A plurality of such gate electrodes are provided in parallel columns, respectively. Conventionally, the terminal ends of a MOSFET including the outermost two columns, respectively, have the P-type base region 14 extending outwardly further than the P⁺-type contact region 19. According to this conventional terminal end structure, the P-type base region 14 causes an increase in region where electric charges are accumulated in a diode during application of a forward bias. To deal with this problem, according to the fourth embodiment, a mesa is provided to secure increased strength to withstand pressure. That is, the terminal ends of the MOSFET according to the fourth embodiment have a trench 15 occupies as far as the outer periphery as shown in FIG. 6.

In FIG. 6, the illustrated trench 15 has its outer (or right) sidewall removed. On the inner or left side of the trench 15, the P-type base region 14 formed on the N⁻-type semiconductor layer 13 and the P⁺-type contact region 19 are laminated, and the trench 15 has the gate electrode of polycrystalline silicon 17 completely surrounded by insulator 16. The illustrated terminal end structure is a rightward, with respect to a direction orthogonal to a juxtaposed column arrangement if each column is directed as shown in FIG. 2, outermost terminal end including a rightward outermost column. In the terminal end, the N⁺-type source region is not needed and the P⁺-type contact region only is provided. This is to positively avoid formation of channel taking into account the fact that electric current concentrates easily on the peripheral portion to break it easily. Comparing FIG. 6 to FIG. 4 clearly reveals that the N⁺-type semiconductor layer 13, P-type base region 14 and P⁺-type contact region 19 have been removed from area on the right side of the trench 15 to provide the illustrated structure in FIG. 6 and gate insulator 16 fills the trench 15 to surround completely the gate electrode of polycrystalline silicon 17. This structure ensures increased breakdown voltage at the terminal ends of the MOSFET by forming a mesa,

### Fifth Embodiment

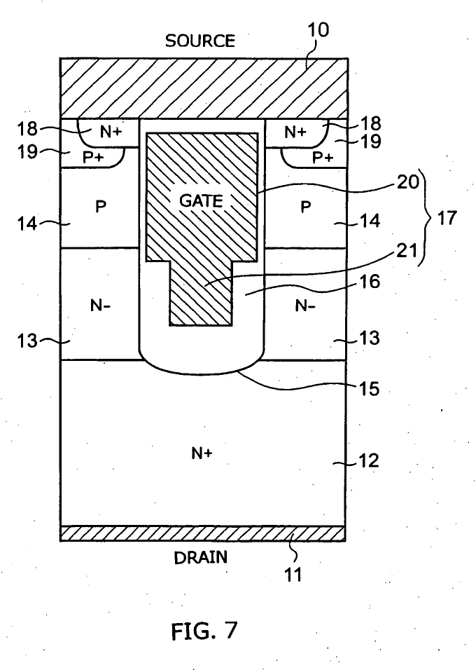

Referring to FIG. 7, a MOSFET according to the fifth embodiment is described. This fifth embodiment is substantially the same as the first embodiment shown in FIG. 1 except that a gate electrode of polycrystalline silicon has an integral bottom protrusion in addition to a main body that is substantially the same as the gate electrode of polycrystalline silicon 17 used in the first embodiment shown in FIG. 1. The bottom integral protrusion has a cross sectional area less than a cross section area of the main body and joins the main body at a lower end surface thereof to define a shoulder. The integral bottom protrusion extends into a bottom thick insulator. The gate electrode of crystalline silicon with the integral bottom protrusion may be equally applicable to the second, third and fourth embodiments.

In FIG. 7, a gate electrode of crystalline silicon 17 is provided to fill a trench 15 after a thick bottom insulator 26 and a thin gate insulator 16 have been formed. The gate electrode of crystalline silicon 17 includes a main body 20 surrounded by the thin gate insulator 16 and an integral bottom protrusion 21. The integral bottom protrusion 21 joins the main body 20 at a lower end surface of the main body 20 to define a shoulder on the lower end surface. The integral bottom protrusion 21 extends into the thick bottom insulator 26 that extends between the lower end surface of the main body 20 and an N⁺-type semiconductor substrate 12. The integral bottom protrusion 21 is insulated from the N⁻-type semiconductor layer 13 by the thick bottom insulator 26.

This gate structure further accelerates the depletion of the N⁻-type semiconductor layer 13 acting as a drift layer via the gate electrode, making it possible to increase the impurity concentration within the N⁻-type semiconductor layer 13. This increased impurity concentration makes it possible to reduce the on-resistance as compared to the MOSFET according to the first embodiment shown in FIG. 1.

### Sixth Embodiment

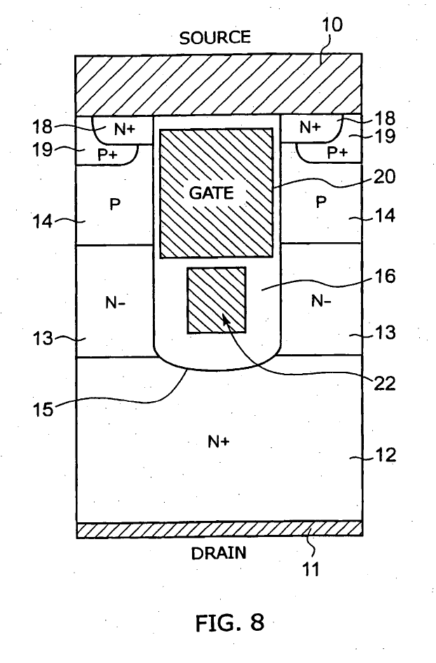

Referring to FIG. 8, a MOSFET according to the sixth embodiment is described. This sixth embodiment is substantially the same as the first embodiment shown in FIG. 1 except that a separate or floating electrode 22 is provided in addition to a gate electrode 20 that is substantially the same as the gate electrode of polycrystalline silicon 17 used in the first embodiment shown in FIG. 1. This sixth embodiment is intended to solve a problem encountered in the fifth embodiment shown in FIG. 7. In the fifth embodiment shown in FIG. 7, the integral bottom protrusion 21 is opposed to a drain contact 10, causing an increase in gate drain capacitance Cgd. In order to avoid this increase in gate drain capacitance Cgd, in the sixth embodiment shown in FIG. 8, the integral bottom electrode 21 shown in FIG. 7 is no longer needed and replaced by the separate or floating electrode 22 having a floating potential. That is, a separate electrode 22 having a floating potential is provided by dividing a bottom integral protrusion 21 from and in addition to the gate electrode 20 through an insulator 16.

The structure on both sides of a trench 15 is substantially the same as that shown in FIG. 1. An N⁺-type semiconductor substrate 14, an N⁻-type semiconductor layer 13 or a drift layer, a P-type base region 14, an N⁺-type source region 18 and a P⁺-type contact region 19 are provided in the manner as illustrated in FIG. 1.

As mentioned before, the fifth embodiment shown in FIG. 7 has a problem that as it opposed to the drain contact 10, the integral bottom protrusion 21 causes an increase in gate drain capacitance Cgd. On the contrary, in the MOSFET according to the sixth embodiment shown in FIG. 8, the separate or flowing electrode 20, which is disposed in a thick bottom insulator 26 and interposed by the N⁻-type semiconductor layer 13 via the thick bottom insulator 26, is insulated from the gate electrode 20 and has a flowing potential that is different from a potential of the gate electrode 20, so that the MOSFET according to this sixth embodiment shown in FIG. 8 may reduce gate drain capacitance as compared to the MOSFET according to the fifth embodiment shown in FIG. 7.

### Seventh Embodiment

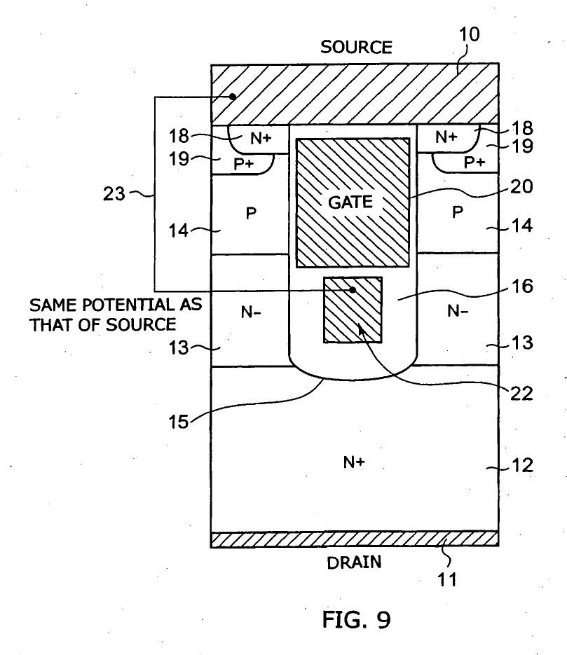

Referring to FIG. 9, a MOSFET according to the seventh embodiment is described. This seventh embodiment shown in FIG. 9 is substantially the same as the sixth embodiment shown in FIG. 8 except that a separate electrode 22 has the same potential as that of a source contact. In the MOSFET according to the sixth embodiment shown in FIG. 8, the gate drain capacitance Cgd is considered as a parallel connection of a capacitance between the gate and the floating electrode and a capacitance between the floating electrode and the drain because the flowing electrode 22 insulated from the gate electrode 20 has a floating potential.

In the MOSFET according to the seventh embodiment shown in FIG. 9, the separate electrode 22 has the same potential as that of the source contact 10 because the separate electrode 22 is electrically connected to the base contact 10 via a line 22. This electrical connection shields the electric field between the gate and drain and reduces the gate drain capacitance Cgd as compared to the sixth embodiment shown in FIG. 8. Depletion of the N⁻-type semiconductor layer 13 acting as a drift layer is accelerated via the separate electrode 22, making it possible to increase the concentration of N⁻-type impurity within the N⁻-type semiconductor layer 13. This increased impurity concentration makes it possible to reduce the on-resistance.

### Eighth Embodiment

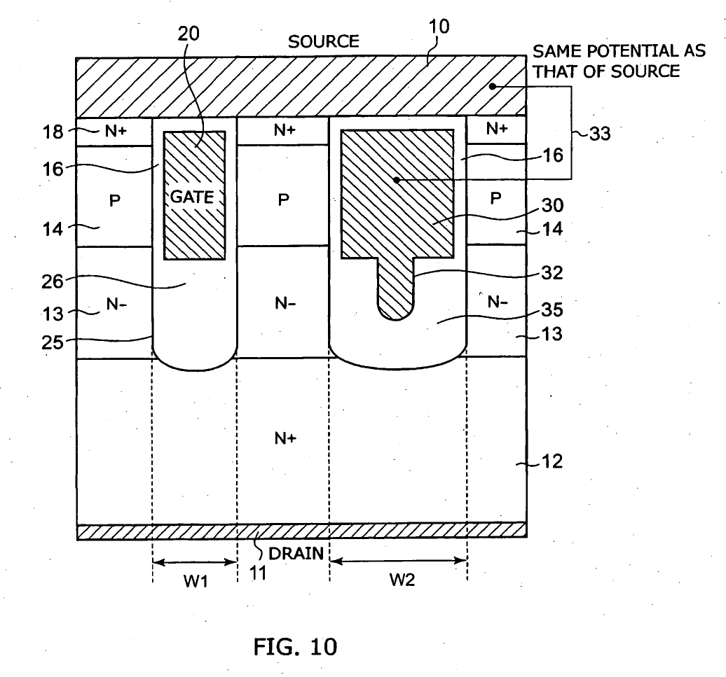

Referring to FIG. 10, a MOSFET according to the eighth embodiment is described. In this eighth embodiment, the adjacent two trenches have different widths. In FIG. 8, the MOSFET is formed with a first trench 25 having a width W1 and a second trench 35 having a width W2, and the first and second trenches 25 and 35 are formed alternately. Formed within the first trench 25 having width W1 is a gate electrode 20 that is described in the first embodiment shown in FIG. 1. Formed within the second trench 35 having width W2 is a gate electrode 30 having an integral bottom protrusion 32. The gate electrode 30 is electrically connected to a source contact 10 via a connecting line 33 and thus has the same potential as that of the source contact 10.

The other construction in FIG. 10 particularly around the trenches 25 and 35 includes the provision of an N⁺-semiconductor substrate 12, an N⁻-semiconductor layer 13 acting as a drift layer, a P-type base region 14, and an N⁺-type source region 18. Depletion of the N⁻-type semiconductor layer 13 or drift layer via the gate electrode 30 is accelerated, making it possible to increase the concentration of N⁻-type impurity within the N⁻-type semiconductor layer 13. This increased impurity concentration makes it possible to reduce the on-resistance. It may be understood that FIG. 10 illustrating the eighth embodiment corresponds to an illustration of a cross sectional representation taken through the line Y-Y′ in FIG. 2 illustrating the second embodiment illustrated.

Throughout each of the first to eighth embodiments, the first conductivity type refers to N-type and the second conductivity type refers to P-type. However, the present embodiment should not be limited to this interpretation. The first conductivity type may refer to P-type and the second conductivity type may refer to N-type.

In the drawings and specification, there have been disclosed typical embodiments and, although specific terms are employed, they are used in a generic and descriptive sense only and not for purposes of limitation, the scope of the following claims.

As described above, the conventional MOSFET has a trade-off that an increase in the gate resistance needs to be considered to optimally set the capacity ratio Cgd/Cgs. It also has a great loss because the diode reverse recovery current is large. Taking into account these problems in the conventional MOSFET, an object of the present invention is to provide a semiconductor device, including a MOSFET, which provides an improved trade-off between the capacity ratio Cgd/Cgs and gate resistance and a reduced diode reverse recovery current. Therefore, the trade-off between the capacity ratio Cgd/Cgs and the gate resistance has been improved and the diode reverse recovery current has been reduced.

What is claimed is:

1. A semiconductor device, comprising:
a semiconductor substrate of a first conductivity type;
a semiconductor layer of the first conductivity type formed on the semiconductor substrate;
a base layer of a second conductivity type formed in a surface of the semiconductor layer;
a gate insulator formed on sidewalls of each of a plurality of trenches formed through the base layer;
a bottom insulator formed at a bottom of each of the trenches and extending through the semiconductor layer and into the semiconductor substrate;
a gate electrode provided in each of the trenches and insulated from the semiconductor substrate, semiconductor layer and base layer by the bottom and gate insulators;
source regions of the first conductivity type formed in a surface of the base layer;
contact regions of the second conductivity type formed in the surface of the base layer;
the bottom insulator having a thickness extending between the semiconductor substrate and the gate electrode,
the gate insulator having a thickness extending between the base layer and the gate electrode,
the thickness of the bottom insulator being greater than the thickness of the gate insulator,
the adjacent two of the trenches each having a width greater than a distance between the adjacent two trenches.

2. The semiconductor device as claimed in claim 1, wherein the distance between the adjacent two trenches is less than or equal to 1 μm.

3. The semiconductor device as claimed in claim 1, wherein the contact regions of the second conductivity type and the source regions of the first conductivity type are in orthogonal relationship to a direction in which electric current flows.

4. The semiconductor device as claimed in claim 1, further comprising a source electrode which is further formed through a top metallization contacting with both the source regions of the first conductivity type and base contact regions of the second conductivity type.

5. The semiconductor device as claimed in claim 1, further comprising a drain electrode which is further formed through a bottom metallization on a lower surface of the semiconductor substrate of the first conductivity.

6. The semiconductor device as claimed in claim 1, wherein the gate electrode is in orthogonal relationship to a direction in which electric current flows, the contact regions of the second conductivity type and the source regions of the first conductivity type are in orthogonal relationship to a direction in which electric current flows and are formed in one plane in juxtaposed relationship.

7. The semiconductor device as claimed in claim 1, wherein the gate electrode undulates across a direction in which electric current flows.

8. The semiconductor device as claimed in claim 1, wherein the gate electrode has a zigzag shape being across a direction in which current flows.

9. The semiconductor device as claimed in claim 1, wherein the trench is formed further outwardly to the outer periphery of the device at each of terminal ends of the device.

10. The semiconductor device as claimed in claim 9, wherein the gate electrode is formed in the trench, and polycrystalline silicon forming the gate electrode is completely surrounded by insulator.

11. The semiconductor device as claimed in claim 1, wherein the gate electrode has a bottom integral protrusion having a cross sectional width less than that of a main gate body and joining the main gate body at a lower end surface thereof to define a shoulder.

12. The semiconductor device as claimed in claim 1, wherein further comprising a separate electrode having a floating potential is provided by dividing a bottom integral protrusion from a bottom surface of a main gate body and in addition to the gate electrode through an insulator.

13. The semiconductor device as claimed in claim 1, further comprising a source electrode which is further formed through a top metallization contacting with both the source regions of the first conductivity type source and base contact regions of the second conductivity type, and
a separate electrode which is provided by dividing a bottom integral protrusion from a bottom surface of a main gate body and in addition to the gate electrode through an insulator, in which the separate electrode has a same potential as that of the source electrode by connecting the separate and source electrodes.

14. The semiconductor device as claimed in claim 13, further comprising a connecting line which is provided between the source electrode and the separate electrode.

15. The semiconductor device as claimed in claim 1, wherein the plurality of trenches are formed in separate, adjacent two trenches of the plurality of trenches have a first trench having a first width and a second trench having a second width, and the first and second trenches are formed alternately.

16. The semiconductor device as claimed in claim 15, wherein the thickness of the bottom insulator extending between the semiconductor substrate and the gate electrode in the first and second trenches is greater than the thickness of the gate insulator between the gate electrode and the base layer of the second conductivity type, respectively, and the widths of the first and second trenches are greater than a distance between the adjacent two trenches, respectively.

17. The semiconductor device as claimed in claim 16, wherein the gate electrode in the second trench has a bottom integral protrusion having a cross sectional width less than that of a main gate body and joining the main gate body at a lower end surface thereof to define a shoulder.

18. The semiconductor device as claimed in claim 17, further comprising a source electrode which is further provided by forming through a top metallization contacting with both the source regions of the first conductivity type and base contact regions of the second conductivity type, and
the bottom integral protrusion of the gate electrode which has the same potential as that of the source electrode by connecting the gate and source electrodes.

19. The semiconductor device as claimed in claim 1, wherein the first conductivity type is an N-type, and the second conductivity type is a P-type.

20 The semiconductor device as claimed in claim 1, wherein the first conductivity type is a P-type, and the second conductivity type is an N-type.
